(19) United States
(12) Patent Application Publication
(10) Pub. No.: US 2007/0138918 A1
(43) Pub. Date: Jun. 21, 2007

(54) Piezoelectric ceramic and piezoelectric ceramic element

(75) Inventors: Yukako Takahashi, Nagaokakyo-shi (JP); Toshikazu Takeda, Omihachiman-shi (JP)

Correspondence Address: DICKSTEIN SHAPIRO LLP, 1177 AVENUE OF THE AMERICAS (6TH AVENUE), NEW YORK, NY, 10036-2714, US

(73) Assignee: MURATA MANUFACTURING CO., LTD., Kyoto-Fu (JP)

(21) Appl. No.: 11/705,527

(22) Filed: Feb. 13, 2007

Related U.S. Application Data
(63) Continuation of application No. PCT/JP05/12699, filed on Jul. 8, 2005.

(30) Foreign Application Priority Data
Sep. 9, 2004 (JP) 2004-263082

(51) Int. Cl. H01L 41/187

(52) U.S. Cl. 310/358

(57) ABSTRACT

A piezoelectric ceramic containing a primary component having a composition represented by Ag_{1-x-y}LiₓK_{y})NbO₃ (in which 0.075≦x<0.4 and 0.03≦y<0.3) and at least one metal oxide of Fe, Co, Ni, Cu, Zn, and Bi in an amount of 0.01 to 10 parts by weight in the form of MO₂ (in which M indicates Fe, Co, Ni, Cu, Zn and Bi) to 100 parts by weight of the primary component.

This is a continuation of application Serial Number PCT/JP2005/012699,filed Jul. 8, 2005.

### TECHNICAL FIELD

The present invention relates to a piezoelectric ceramic and a piezoelectric ceramic element, and more particularly, relates to a piezoelectric ceramic preferably used as a material for a piezoelectric ceramic element such as a piezoelectric ceramic filter, an actuator and a piezoelectric ceramic oscillator, and to a piezoelectric ceramic element using the piezoelectric ceramic.

### BACKGROUND ART

For a piezoelectric ceramic element such as a piezoelectric ceramic filter, a piezoelectric ceramic primarily composed of lead titanate zirconate (Pb(TiₓZr₁₋ₓ)O₃) or lead titanate (PbTiO₃) has been widely used.

However, since a piezoelectric ceramic primarily composed of lead titanate zirconate or lead titanate contains harmful lead, affects on the human body and the environment, which are caused when the piezoelectric ceramic is manufactured and/or discarded, have been problems. In addition, during the manufacturing process, since a lead component used as a raw material is evaporated, there has been a problem of degradation in uniformity of quality of the piezoelectric ceramic.

A piezoelectric ceramic containing no lead has been proposed in Patent Document 1. This piezoelectric ceramic includes a perovskite oxide composed of a first element containing sodium (Na), potassium (K), lithium (Li) and silver (Ag); a second element containing at least niobium (Nb) of the group consisting of niobium (Nb) and tantalum (Ta); and oxygen (O). When this piezoelectric ceramic is manufactured, by firing at a temperature of 950 to 1,350° C., a piezoelectric ceramic having a relative dielectric constant εᵣ of 412 to 502, an electromechanical coupling factor κᵣ of 38% to 42%, and a generated displacement of 0.064% to 0.075% is obtained.

Patent Document 1: Japanese Unexamined Patent Application Publication No. 2003-277145

### DISCLOSURE OF INVENTION

Problems to be Solved by the Invention

The firing temperature is high, such as 950 to 1,350° C., when a piezoelectric ceramic element is manufactured in the case of the piezoelectric ceramic disclosed in Patent Document 1, and very expensive Pd or a Pd—Ag alloy containing Pd at a high concentration must be disadvantageously used for an internal electrode which is fired together with the piezoelectric ceramic.

The present invention was made in order to solve the above problem, and an object of the present invention is to provide a piezoelectric ceramic which can be fired at a low temperature, such as 1,000° C. or less, without degrading piezoelectric properties, such as the electromechanical coupling factor and the piezoelectric constant, and a piezoelectric ceramic element.

Means for Solving the Problems

A piezoelectric ceramic according to the present invention contains a primary component having a composition represented by (Ag_{1-x-y}LiₓK_{y})NbO₃ (in which 0.075≦x<0.4 and 0.03≦y<0.3 hold) and at least one metal oxide of Fe, Co, Ni, Cu, Zn and Bi in an amount of 0.01 to 10 parts by weight in the form of MO₂ (in which M indicates Fe, Co, Ni, Cu, Zn and Bi) with respect to 100 parts by weight of the primary component.

In addition, in the piezoelectric ceramic according to claim 1, an oxide of Mn and/or an oxide of Si may be contained in an amount of 5 parts by weight or less in the form of MnO₂ and SiO₂, respectively, with respect to 100 parts by weight of the primary component.

A piezoelectric ceramic element includes the above piezoelectric ceramic and electrodes formed for the piezoelectric ceramic.

Accordingly, the piezoelectric ceramic of the present invention contains a perovskite oxide (ABO₃) having a composition represented by (Ag_{1-x-y}LiₓK_{y})NbO₃ (in which 0.075≦x<0.4 and 0.03≦y<0.3). That is, the primary component of the present invention is a perovskite oxide having AgNbO₃ as a basic composition, and the Ag of the A site is partly replaced with a monovalent Li and/or K. The piezoelectric ceramic of the present invention is primarily composed of a perovskite oxide containing no Pb which is a harmful substance.

When the amount x of Li for replacing Ag satisfies the relationship represented by 0.075≦x<0.4, and the amount y of K for replacing Ag satisfies the relationship represented by 0.03≦y<0.3, the Curie point (polarization disappearance temperature: temperature at which a crystalline system exhibiting piezoelectric properties is phase-transitioned into a crystalline system showing no piezoelectric properties by temperature rise) is 350° C. or more.

When the amount x of Li for replacing Ag is either less than 0.075 or 0.4 or more, the Curie point is decreased to less than 350° C., and a practical problem may occur in some cases. In addition, when the amount y of K for replacing Ag is either less than 0.03 or 0.3 or more, as is the case of Li, the Curie point is decreased to less than 350° C.

In addition, since the contents of Li and K, which are alkaline components in the above composition, are smaller than those in the conventional piezoelectric ceramic proposed, for example, in Patent Document 1, and the content of Ag is therefore large, variation in piezoelectric properties caused by vaporizing the alkaline components and the unstableness of reproducibility can be reduced.

By adding an oxide of at least one type of metal element selected from the group consisting of Fe, Co, Ni, Cu, Zn and Bi as a first accessory component, the firing temperature can be decreased to 1,000° C. or less, and problems caused, for example, by vaporizing the contained elements can be prevented, and furthermore, a piezoelectric ceramic can be obtained which has superior piezoelectric properties, such as the relative dielectric constant εᵣ, electromechanical coupling factor κ₃₃ in a thickness vibration mode, piezoelectric constant d₃₃ in a thickness vibration mode, and resonant frequency constant N in a thickness vibration mode, and which has superior temperature properties such as a Curie point of 350° C. or more.

Since the piezoelectric ceramic can be fired at a low temperature, such as 1,000° C. or less, according to the present invention, when a piezoelectric ceramic element is manufactured, for example, the amount of Pd, which is an expensive metal, or the ratio of Pd of a Ag—Pd alloy can be decreased, and as a result, the manufacturing cost of the piezoelectric ceramic element can be reduced.

When the addition amount (in the form of MO₂) of the first accessory component is less than 0.01 part by weight with respect to 100 parts by weight of the above primary component, the sintering temperature becomes high, such as more than 1,000° C., and when the addition amount is more than 10 parts by weight, the electromechanical coupling factor κ₃₃ is decreased.

In the present invention, besides the first accessory component, an oxide of Mn and/or an oxide of Si is preferably added as a second accessory component in an amount of 5 parts by weight or less in the form of MnO₂ and SiO₂, respectively. By adding the second accessory component, the firing temperature can be further decreased as compared to that when the second accessory component is not added, and furthermore, piezoelectric properties substantially equivalent to those obtained when the second accessory component is not added can be obtained.

Since the piezoelectric ceramic element of the present invention includes the piezoelectric ceramic according to the present invention, harmful Pb is not present, low-temperature firing at 1,000° C. or less can be performed, the Pd content ratio can be decreased even when Pd or a Ag—Pd alloy is used for the electrodes, and the manufacturing cost of the piezoelectric ceramic element can be reduced. In the piezoelectric ceramic of the present invention, any deviation from the chemical stoichiometric composition represented by the above composition formula may be caused by the impurities in the starting materials, preparation method, firing conditions and the like for manufacturing can be tolerated as long as the ceramic is not substantially deteriorated. As long as the object of the present invention is not deteriorated, a slight amount of impurities may be contained.

Advantages

A piezoelectric ceramic element can be provided without degrading the piezoelectric properties, such as the electromechanical coupling factor and the piezoelectric constant, a piezoelectric ceramic, which can be fired at a low temperature of 1,000° C. or less.

### BRIEF DESCRIPTION OF THE DRAWINGS

FIG. 1 is a perspective view showing a piezoelectric ceramic vibrator according to one embodiment of a piezoelectric ceramic element of the present invention.

FIG. 2 is a cross-sectional view of the piezoelectric ceramic element shown in FIG. 1.

### REFERENCE NUMERALS

10 piezoelectric ceramic element

11 piezoelectric ceramic

12A, 12B, 12C vibration electrode

13A, 13B, 13C lead electrode

### BEST MODE FOR CARRYING OUT THE INVENTION

Next, a piezoelectric ceramic of the present invention will be described with reference to particular examples.

### Example 1

(1) Preparation of Primary Component

As starting materials for a primary component, Ag₂O, Nb₂O₅, Li₂CO₃ and K₂CO₃ in powder form were first prepared and were then weighed so that x and y of (Ag_{1-x-y}LiₓK_{y})NbO₃ had composition ratios shown in Tables 1 to 6, thereby forming preparations to be formed into sample Nos. 1 to 146. Subsequently, the preparations thus obtained were calcined at 800 to 900° C. for 10 hours in an oxidizing atmosphere in an electric furnace, thereby obtaining calcined powders. Samples provided with * in the tables have compositions which are out of the range of the present invention.

(2) Addition of First Accessory Component

As a first accessory component, Bi₂O₃, ZnO, CuO, NiO, CoCO₃ and Fe₂O₃ in powder form were weighed and were added with respect to 100 parts by weight of the above primary component so that composition ratios shown in Tables 1 to 6 were obtained. Subsequently, after mixing, 5 parts by weight of polyvinyl alcohol as an organic binder was added with respect to 100 parts by weight of the above raw-material mixed powder to form a slurry, and wet pulverization was then performed, followed by drying, so that a dried powder was obtained.

(3) Preparation of Samples

Subsequently, the dried powders thus obtained were each formed into a block-shaped sample having a length of 12 mm, a breadth of 12 mm, and a thickness of 2.5 mm by a uniaxial pressing (980 MPa). The samples thus obtained were fired at the temperatures shown in Tables 1 to 6 in an oxidizing atmosphere. Then, after a Ag paste was applied onto two major surfaces of the samples, and firing was performed at 800° C. Subsequently, a polarization treatment was performed in a temperature range of room temperature to 150° C. in an insulating oil bath by applying a direct-current voltage of 50 to 200 kV/cm for 3 to 10 minutes. Next, the samples thus processed were each machined into a block having a size of 2 mm×2 mm×3 mm using a dicing machine, so that sample Nos. 1 to 146 shown in Tables 1 to 6 were formed.

TABLE 1
AMOUNT OF Bi₂O₃ IN THE RANGE OF 0.01 TO 10 PARTS BY
WEIGHT IN THE FORM OF BiO₂

| | | x | y | | (° C.) |
|---|---|---|---|---|---|
| * | 1 | 0.050 | 0.03 | 5.00 | 980 |
| * | 2 | 0.075 | 0.00 | 5.00 | 960 |
| * | 3 | 0.075 | 0.03 | 0.00 | 1020 |
| | 4 | 0.075 | 0.03 | 0.01 | 960 |
| | 5 | 0.075 | 0.03 | 5.00 | 960 |
| | 6 | 0.075 | 0.03 | 10.00 | 940 |
| * | 7 | 0.075 | 0.03 | 11.00 | 940 |
| * | 8 | 0.075 | 0.20 | 0.00 | 1020 |
| | 9 | 0.075 | 0.20 | 0.01 | 980 |
| | 10 | 0.075 | 0.20 | 5.00 | 980 |
| | 11 | 0.075 | 0.20 | 10.00 | 960 |
| * | 12 | 0.075 | 0.20 | 11.00 | 960 |
| * | 13 | 0.075 | 0.30 | 5.00 | 980 |
| | 14 | 0.200 | 0.10 | 0.01 | 960 |
| | 15 | 0.200 | 0.10 | 5.00 | 940 |
| | 16 | 0.200 | 0.10 | 10.00 | 940 |
| * | 17 | 0.300 | 0.03 | 0.00 | 1020 |
| | 18 | 0.300 | 0.03 | 0.01 | 960 |
| | 19 | 0.300 | 0.03 | 5.00 | 960 |
| | 20 | 0.300 | 0.03 | 10.00 | 940 |
| * | 21 | 0.300 | 0.03 | 11.00 | 940 |
| * | 22 | 0.300 | 0.20 | 0.00 | 1020 |
| | 23 | 0.300 | 0.20 | 0.01 | 960 |
| | 24 | 0.300 | 0.20 | 5.00 | 940 |
| | 25 | 0.300 | 0.20 | 10.00 | 940 |
| * | 26 | 0.300 | 0.20 | 11.00 | 940 |
| * | 27 | 0.400 | 0.20 | 5.00 | 960 |
| * | 28 | 0.400 | 0.03 | 5.00 | 960 |

TABLE 2
AMOUNT ZnO IN THE RANGE OF 0.01 TO 10 PARTS
BY WEIGHT IN THE FORM OF ZnO₂

| | | x | y | | (° C.) |
|---|---|---|---|---|---|
| * | 29 | 0.050 | 0.03 | 5.00 | 980 |
| * | 30 | 0.075 | 0.00 | 5.00 | 980 |
| | 31 | 0.075 | 0.03 | 0.01 | 960 |
| | 32 | 0.075 | 0.03 | 5.00 | 960 |
| | 33 | 0.075 | 0.03 | 10.00 | 940 |
| * | 34 | 0.075 | 0.03 | 11.00 | 940 |
| | 35 | 0.075 | 0.20 | 0.01 | 980 |
| | 36 | 0.075 | 0.20 | 5.00 | 960 |
| | 37 | 0.075 | 0.20 | 10.00 | 960 |
| * | 38 | 0.075 | 0.20 | 11.00 | 960 |
| * | 39 | 0.075 | 0.30 | 5.00 | 980 |
| | 40 | 0.200 | 0.10 | 0.01 | 980 |
| | 41 | 0.200 | 0.10 | 5.00 | 940 |
| | 42 | 0.200 | 0.10 | 10.00 | 940 |
| | 43 | 0.300 | 0.03 | 0.01 | 960 |
| | 44 | 0.300 | 0.03 | 5.00 | 960 |
| | 45 | 0.300 | 0.03 | 10.00 | 940 |
| * | 46 | 0.300 | 0.03 | 11.00 | 940 |
| | 47 | 0.300 | 0.20 | 0.01 | 960 |
| | 48 | 0.300 | 0.20 | 5.00 | 960 |
| | 49 | 0.300 | 0.20 | 10.00 | 940 |
| * | 50 | 0.300 | 0.20 | 11.00 | 940 |
| * | 51 | 0.400 | 0.20 | 5.00 | 960 |
| * | 52 | 0.400 | 0.03 | 5.00 | 960 |

TABLE 3
AMOUNT CuO IN THE RANGE OF 0.01 TO 10 PARTS
BY WEIGHT IN THE FORM OF CuO₂

| | | x | y | | (° C.) |
|---|---|---|---|---|---|
| * | 53 | 0.050 | 0.03 | 5.00 | 980 |
| * | 54 | 0.075 | 0.00 | 5.00 | 980 |
| | 55 | 0.075 | 0.03 | 0.01 | 1000 |
| | 56 | 0.075 | 0.03 | 5.00 | 980 |
| | 57 | 0.075 | 0.03 | 10.00 | 960 |
| * | 58 | 0.075 | 0.03 | 11.00 | 940 |
| | 59 | 0.075 | 0.20 | 0.01 | 980 |
| | 60 | 0.075 | 0.20 | 5.00 | 960 |
| | 61 | 0.075 | 0.20 | 10.00 | 960 |
| * | 62 | 0.075 | 0.20 | 11.00 | 960 |
| * | 63 | 0.075 | 0.30 | 5.00 | 980 |
| | 64 | 0.200 | 0.10 | 0.01 | 980 |
| | 65 | 0.200 | 0.10 | 5.00 | 960 |
| | 66 | 0.200 | 0.10 | 10.00 | 960 |
| | 67 | 0.300 | 0.03 | 0.01 | 940 |
| | 68 | 0.300 | 0.03 | 5.00 | 940 |
| | 69 | 0.300 | 0.03 | 10.00 | 940 |
| * | 70 | 0.300 | 0.03 | 11.00 | 940 |
| | 71 | 0.300 | 0.20 | 0.01 | 960 |
| | 72 | 0.300 | 0.20 | 5.00 | 940 |
| | 73 | 0.300 | 0.20 | 10.00 | 940 |
| * | 74 | 0.300 | 0.20 | 11.00 | 940 |
| * | 75 | 0.400 | 0.20 | 5.00 | 960 |
| * | 76 | 0.400 | 0.03 | 5.00 | 940 |

TABLE 4
AMOUNT NiO IN THE RANGE OF 0.01 TO 10 PARTS
BY WEIGHT IN THE FORM OF NiO₂

| | | x | y | | (° C.) |
|---|---|---|---|---|---|
| * | 77 | 0.050 | 0.03 | 5.00 | 980 |
| * | 78 | 0.075 | 0.00 | 5.00 | 980 |
| | 79 | 0.075 | 0.03 | 0.01 | 1000 |
| | 80 | 0.075 | 0.03 | 5.00 | 960 |
| | 81 | 0.075 | 0.03 | 10.00 | 960 |
| * | 82 | 0.075 | 0.03 | 11.00 | 940 |
| | 83 | 0.075 | 0.20 | 0.01 | 940 |
| | 84 | 0.075 | 0.20 | 5.00 | 980 |
| | 85 | 0.075 | 0.20 | 10.00 | 980 |
| * | 86 | 0.075 | 0.20 | 11.00 | 980 |
| * | 87 | 0.075 | 0.30 | 5.00 | 960 |
| | 88 | 0.200 | 0.10 | 0.01 | 960 |
| | 89 | 0.200 | 0.10 | 5.00 | 980 |
| | 90 | 0.200 | 0.10 | 10.00 | 960 |
| | 91 | 0.300 | 0.03 | 0.01 | 940 |
| | 92 | 0.300 | 0.03 | 5.00 | 940 |
| | 93 | 0.300 | 0.03 | 10.00 | 980 |
| * | 94 | 0.300 | 0.03 | 11.00 | 960 |
| | 95 | 0.300 | 0.20 | 0.01 | 960 |
| | 96 | 0.300 | 0.20 | 5.00 | 940 |
| | 97 | 0.300 | 0.20 | 10.00 | 940 |
| * | 98 | 0.300 | 0.20 | 11.00 | 980 |
| * | 99 | 0.400 | 0.20 | 5.00 | 960 |
| * | 100 | 0.400 | 0.03 | 5.00 | 940 |

TABLE 5
AMOUNT CoCO₃ IN THE RANGE OF 0.01 TO 10 PARTS BY
WEIGHT IN THE FORM OF CoO₂

| | | x | y | | (° C.) |
|---|---|---|---|---|---|
| * | 101 | 0.050 | 0.03 | 5.00 | 980 |
| * | 102 | 0.075 | 0.00 | 5.00 | 980 |
| | 103 | 0.075 | 0.03 | 0.01 | 1000 |
| | 104 | 0.075 | 0.03 | 5.00 | 960 |
| | 105 | 0.075 | 0.03 | 10.00 | 960 |
| * | 106 | 0.075 | 0.03 | 11.00 | 940 |
| | 107 | 0.075 | 0.20 | 0.01 | 940 |
| | 108 | 0.075 | 0.20 | 5.00 | 980 |
| | 109 | 0.075 | 0.20 | 10.00 | 980 |
| * | 110 | 0.075 | 0.20 | 11.00 | 980 |
| * | 111 | 0.075 | 0.30 | 5.00 | 960 |
| | 112 | 0.200 | 0.10 | 5.00 | 960 |
| | 113 | 0.200 | 0.10 | 10.00 | 960 |
| | 114 | 0.300 | 0.03 | 0.01 | 980 |
| | 115 | 0.300 | 0.03 | 5.00 | 960 |
| | 116 | 0.300 | 0.03 | 10.00 | 960 |
| * | 117 | 0.300 | 0.03 | 11.00 | 960 |
| | 118 | 0.300 | 0.20 | 0.01 | 960 |
| | 119 | 0.300 | 0.20 | 5.00 | 940 |
| | 120 | 0.300 | 0.20 | 10.00 | 940 |
| * | 121 | 0.300 | 0.20 | 11.00 | 940 |
| * | 122 | 0.400 | 0.20 | 5.00 | 960 |
| * | 123 | 0.400 | 0.03 | 5.00 | 960 |

TABLE 6
AMOUNT Fe₂O₃ IN THE RANGE OF 0.01 TO 10 PARTS
BY WEIGHT IN THE FORM OF FeO₂

| | | x | y | | (° C.) |
|---|---|---|---|---|---|
| * | 124 | 0.050 | 0.03 | 5.00 | 980 |
| * | 125 | 0.075 | 0.00 | 5.00 | 980 |
| | 126 | 0.075 | 0.03 | 0.01 | 1000 |
| | 127 | 0.075 | 0.03 | 5.00 | 980 |
| | 128 | 0.075 | 0.03 | 10.00 | 980 |
| * | 129 | 0.075 | 0.03 | 11.00 | 960 |
| | 130 | 0.075 | 0.20 | 0.01 | 980 |
| | 131 | 0.075 | 0.20 | 5.00 | 980 |
| | 132 | 0.075 | 0.20 | 10.00 | 940 |
| * | 133 | 0.075 | 0.20 | 11.00 | 940 |
| * | 134 | 0.075 | 0.30 | 5.00 | 960 |
| | 135 | 0.200 | 0.10 | 5.00 | 960 |
| | 136 | 0.200 | 0.10 | 10.00 | 960 |
| | 137 | 0.300 | 0.03 | 0.01 | 960 |
| | 138 | 0.300 | 0.03 | 5.00 | 940 |
| | 139 | 0.300 | 0.03 | 10.00 | 940 |
| * | 140 | 0.300 | 0.03 | 11.00 | 980 |
| | 141 | 0.300 | 0.20 | 0.01 | 960 |
| | 142 | 0.300 | 0.20 | 5.00 | 940 |
| | 143 | 0.300 | 0.20 | 10.00 | 940 |
| * | 144 | 0.300 | 0.20 | 11.00 | 980 |
| * | 145 | 0.400 | 0.20 | 5.00 | 980 |
| * | 146 | 0.400 | 0.03 | 5.00 | 940 |

(4) Evaluation of Samples

The relative dielectric constant εᵣ, electromechanical coupling factor κ₃₃ in a thickness vibration mode, piezoelectric constant d₃₃ in a thickness vibration mode, resonant frequency constant N in a thickness vibration mode, and the Curie point of each of the above samples shown in Tables 1 to 6 were measured, and the results thereof are shown in Tables 7 to 12.

TABLE 7

| | | | (%) | (pC/N) | (Hz · m) | (° C.) |
|---|---|---|---|---|---|---|
| * | 1 | 393 | 33 | 41 | 2139 | 160 |
| * | 2 | 189 | 37 | 45 | 2043 | 290 |
| * | 3 | 251 | 49 | 60 | 2253 | 350 |
| | 4 | 260 | 47 | 56 | 2308 | 355 |
| | 5 | 255 | 38 | 48 | 2381 | 360 |
| | 6 | 257 | 34 | 45 | 2275 | 355 |
| * | 7 | 263 | 19 | 38 | 2756 | 340 |
| * | 8 | 298 | 41 | 52 | 2053 | 340 |
| | 9 | 317 | 37 | 49 | 2237 | 350 |
| | 10 | 330 | 35 | 45 | 2169 | 355 |
| | 11 | 328 | 32 | 41 | 2310 | 350 |
| * | 12 | 346 | 18 | 36 | 2322 | 360 |
| * | 13 | 335 | 39 | 47 | 2261 | 335 |
| | 14 | 255 | 45 | 55 | 2049 | 380 |
| | 15 | 263 | 43 | 54 | 2136 | 375 |
| | 16 | 271 | 38 | 52 | 2189 | 375 |
| * | 17 | 244 | 47 | 60 | 2049 | 360 |
| | 18 | 253 | 42 | 53 | 2099 | 360 |
| | 19 | 259 | 37 | 46 | 2062 | 360 |
| | 20 | 263 | 33 | 41 | 2230 | 365 |
| * | 21 | 266 | 19 | 37 | 2198 | 355 |
| * | 22 | 250 | 53 | 63 | 2055 | 355 |
| | 23 | 255 | 46 | 55 | 2160 | 355 |
| | 24 | 267 | 40 | 52 | 2223 | 350 |
| | 25 | 273 | 33 | 48 | 2236 | 360 |
| * | 26 | 284 | 18 | 36 | 2302 | 360 |
| * | 27 | 253 | 32 | 24 | 1876 | 320 |
| * | 28 | 262 | 32 | 24 | 1876 | 320 |

The results in Table 7 show that in the case in which Bi₂O₃ was added as the first accessory component, the composition of the piezoelectric ceramic was in the range of the present invention (sample Nos. 4 to 6, 9 to 11, 14 to 16, 18 to 20, and 23 to 25), and when the addition amount of Bi₂O₃ was in the range of the present invention, the electromechanical coupling factor κ₃₃, the piezoelectric constant d₃₃, the resonant frequency constant, and the Curie point (hereinafter, those are referred as the “piezoelectric properties”) were maintained at the level at which no practical problems occurred, and firing could be performed at a low temperature of less than 1,000° C., such as 940 to 980° C. Since low-temperature firing can be carried out, the composition ratio of Pd of a Ag—Pd alloy used for an internal electrode of a piezoelectric ceramic element can be decreased, and as a result, the cost reduction can be realized.

On the other hand, in the case of sample No. 1 having a primary-component value x of less than 0.075 (the lower limit of the range according to the present invention, the value x being used to express the primary component having the composition represented by (Ag_{1-x-y}LiₓK_{y})NbO₃) , the Curie point was extremely lower than 350° C., such as 160° C. In the cases of sample Nos. 27 and 28 having a value x of more than 0.4 (which corresponded to the upper limit of the range according to the present invention), the Curie point was less than 350° C., that is, 320° C. In the case of sample No. 2 in which the value y of the above composition was less than 0.03 and in the case of sample No. 13 in which the value y was 0.3 or more, both of which were outside the range of the present invention, the Curie point was less than 350° C.

In the cases of sample Nos. 3, 8, 17 and 22 in which no Bi₂O₃ was added, that is, in which the addition amount of Bi₂O₃ was less than 0.01 part by weight to 100 parts of the primary component (the lower limit of Bi₂O₃ (in the form or BiO₂) of the range according to the present invention), the firing temperatures were all higher than 1,000° C., such as 1,020° C. In the cases of sample Nos. 7, 12, 21 and 26 in which the addition amount of Bi₂O₃ was more than 10 parts by weight (the upper limit of the range according to the present invention), the electromechanical coupling factor κ₃₃ was small, such as less than 20%.

TABLE 8

| | | | (%) | (pC/N) | (Hz · m) | (° C.) |
|---|---|---|---|---|---|---|
| * | 29 | 387 | 34 | 44 | 2144 | 165 |
| * | 30 | 203 | 38 | 47 | 2050 | 290 |
| | 31 | 255 | 46 | 55 | 2256 | 350 |
| | 32 | 263 | 35 | 49 | 2266 | 355 |
| | 33 | 268 | 28 | 45 | 2269 | 355 |
| * | 34 | 270 | 19 | 38 | 2312 | 360 |
| | 35 | 306 | 42 | 54 | 2019 | 370 |
| | 36 | 327 | 45 | 55 | 2213 | 375 |
| | 37 | 331 | 38 | 51 | 2315 | 370 |
| * | 38 | 313 | 18 | 35 | 2330 | 370 |
| * | 39 | 340 | 39 | 47 | 2261 | 330 |
| | 40 | 263 | 44 | 54 | 2057 | 385 |
| | 41 | 265 | 41 | 49 | 2198 | 385 |
| | 42 | 269 | 37 | 42 | 2232 | 380 |
| | 43 | 244 | 47 | 60 | 2049 | 360 |
| | 44 | 253 | 38 | 52 | 2133 | 355 |
| | 45 | 266 | 32 | 43 | 2201 | 360 |
| * | 46 | 259 | 19 | 36 | 2259 | 360 |
| | 47 | 250 | 53 | 63 | 2055 | 355 |
| | 48 | 261 | 45 | 56 | 2156 | 355 |
| | 49 | 262 | 34 | 47 | 2251 | 360 |
| * | 50 | 259 | 18 | 33 | 2267 | 360 |
| * | 51 | 260 | 32 | 24 | 1876 | 320 |
| * | 52 | 267 | 29 | 22 | 1909 | 325 |

The results shown in Table 8 indicate that, even in the case in which ZnO was added as the first accessory component, when the compositions of the piezoelectric ceramics were in the range of the present invention (sample Nos. 31 to 33, 35 to 37, 40 to 45, and 47 to 49), the piezoelectric properties were maintained so as not to cause any practical problems, and furthermore, firing could be performed at a low temperature, such as 1,000° C. or less, as was the case in which Bi₂O₃ was added.

On the other hand, in the cases of sample Nos. 29, 30, 39, 51 and 52 in which the primary component having the composition represented by (Ag_{1-x-y}LiₓK_{y})NbO₃ was outside the ranges (0.075≦x<0.4, 0.03≦y<0.3) of the present invention, the Curie point was less than 350° C., as was the case in which Bi₂O₃ was added.

In the cases of sample Nos. 34, 38, 46 and 50 in which the addition amount of ZnO (in the form of ZnO₂) was more than 10 parts by weight, as was the case in which Bi₂O₃ was added, the electromechanical coupling factor κ₃₃ was small, such as less than 20%.

TABLE 9

| | | | (%) | (pC/N) | (Hz · m) | (° C.) |
|---|---|---|---|---|---|---|
| * | 53 | 365 | 32 | 42 | 2159 | 165 |
| * | 54 | 194 | 37 | 46 | 2230 | 285 |
| | 55 | 247 | 48 | 53 | 2195 | 350 |
| | 56 | 256 | 33 | 45 | 2163 | 350 |
| | 57 | 259 | 25 | 39 | 2251 | 355 |
| * | 58 | 263 | 18 | 32 | 2345 | 350 |
| | 59 | 293 | 32 | 53 | 2091 | 360 |
| | 60 | 301 | 44 | 55 | 2236 | 360 |
| | 61 | 312 | 32 | 52 | 2287 | 360 |
| * | 62 | 315 | 15 | 33 | 2380 | 365 |
| * | 63 | 334 | 38 | 46 | 2198 | 345 |
| | 64 | 257 | 45 | 52 | 2103 | 385 |
| | 65 | 262 | 40 | 47 | 2231 | 380 |
| | 66 | 265 | 36 | 43 | 2197 | 380 |
| | 67 | 235 | 45 | 57 | 2078 | 360 |
| | 68 | 247 | 37 | 51 | 2154 | 360 |
| | 69 | 255 | 30 | 39 | 2243 | 365 |
| * | 70 | 253 | 17 | 34 | 2262 | 365 |
| | 71 | 246 | 51 | 58 | 2076 | 355 |
| | 72 | 253 | 43 | 55 | 2109 | 355 |
| | 73 | 259 | 36 | 48 | 2234 | 355 |
| * | 74 | 250 | 15 | 32 | 2254 | 355 |
| * | 75 | 234 | 33 | 25 | 1832 | 320 |
| * | 76 | 293 | 27 | 21 | 1875 | 320 |

According to the results shown in Table 9, when CuO was added as the first accessory component, and the compositions of the piezoelectric ceramics were in the range of the present invention (sample Nos. 55 to 57, 59 to 61, 64 to 69, and 71 to 73), as was the case in which Bi₂O₃ was added, the piezoelectric properties were maintained so as not to cause any practical problems, and furthermore, firing could be performed at a low temperature, such as 1,000° C. or less.

On the other hand, in the cases of sample Nos. 53, 54, 63, 75 and 76 in which the primary component having the composition represented by (Ag_{1-x-y}LiₓK_{y})NbO₃ was outside the ranges (0.075≦x<0.4, 0.03≦y<0.3) of the present invention, as was the case in which Bi₂O₃ was added, the Curie point was less than 350° C.

In the cases of sample Nos. 58, 62, 70 and 74 in which the addition amount of CuO (in the form of CuO₂) was more than 10 parts by weight, as was the case in which Bi₂O₃ was added, the electromechanical coupling factor κ₃₃ was small, such as less than 20%.

TABLE 10

| | | | (%) | (pC/N) | (Hz · m) | (° C.) |
|---|---|---|---|---|---|---|
| * | 77 | 359 | 33 | 45 | 2234 | 160 |
| * | 78 | 203 | 38 | 49 | 2276 | 280 |
| | 79 | 239 | 46 | 53 | 2206 | 360 |
| | 80 | 249 | 36 | 44 | 2197 | 355 |
| | 81 | 253 | 27 | 37 | 2284 | 355 |
| * | 82 | 262 | 18 | 27 | 2293 | 355 |
| | 83 | 306 | 30 | 41 | 2134 | 350 |
| | 84 | 315 | 31 | 42 | 2246 | 360 |
| | 85 | 322 | 32 | 44 | 2307 | 360 |
| * | 86 | 329 | 16 | 23 | 2341 | 365 |
| * | 87 | 345 | 35 | 48 | 2206 | 340 |
| | 88 | 267 | 41 | 50 | 2203 | 385 |
| | 89 | 273 | 39 | 49 | 2198 | 380 |
| | 90 | 275 | 37 | 47 | 2430 | 380 |
| | 91 | 240 | 43 | 52 | 2201 | 360 |
| | 92 | 251 | 33 | 44 | 2034 | 355 |
| | 93 | 258 | 31 | 43 | 2256 | 355 |
| * | 94 | 249 | 16 | 21 | 2302 | 355 |
| | 95 | 261 | 49 | 56 | 2104 | 355 |
| | 96 | 264 | 45 | 54 | 2189 | 350 |
| | 97 | 273 | 34 | 45 | 2267 | 350 |
| * | 98 | 260 | 17 | 24 | 2301 | 350 |
| * | 99 | 251 | 32 | 43 | 1936 | 315 |
| * | 100 | 278 | 24 | 35 | 1903 | 320 |

Table 10 shows that when NiO was added as the first accessory component, and the compositions of the piezoelectric ceramics were in the range of the present invention (sample Nos. 79 to 81, 83 to 85, 88 to 93, and 95 to 97), as was the case in which Bi₂O₃ was added, the piezoelectric properties were maintained so as not to cause any practical problems, and furthermore, firing could be performed at a low temperature, such as 1,000° C. or less.

On the other hand, in the cases of sample Nos. 77, 78, 87, 99 and 100 in which the primary component having the composition represented by (Ag_{1-x-y}LiₓK_{y})NbO₃ was outside the ranges (0.075≦x<0.4, 0.03≦y<0.3) of the present invention, the Curie point was less than 350° C., as was the case in which Bi₂O₃ was added.

In the cases of sample Nos. 82, 86, 94 and 98 in which the addition amount of NiO (in the form of NiO₂) was more than 10 parts by weight, as was the case in which Bi₂O₃ was added, the electromechanical coupling factor κ₃₃ was small, such as less than 20%.

TABLE 11

| | | | (%) | (pC/N) | (Hz · m) | (° C.) |
|---|---|---|---|---|---|---|
| | 101 | 369 | 32 | 42 | 2089 | 160 |
| * | 102 | 188 | 38 | 47 | 2057 | 285 |
| | 103 | 251 | 45 | 53 | 2198 | 360 |
| | 104 | 255 | 37 | 48 | 2342 | 360 |
| | 105 | 264 | 32 | 44 | 2215 | 355 |
| * | 106 | 269 | 16 | 39 | 2067 | 355 |
| | 107 | 310 | 45 | 54 | 2109 | 360 |
| | 108 | 323 | 41 | 51 | 2165 | 360 |
| | 109 | 337 | 39 | 46 | 2086 | 360 |
| * | 110 | 340 | 18 | 43 | 2046 | 360 |
| * | 111 | 335 | 37 | 47 | 2261 | 330 |
| | 112 | 255 | 42 | 49 | 2057 | 370 |
| | 113 | 262 | 36 | 41 | 2033 | 370 |
| | 114 | 258 | 40 | 50 | 2236 | 365 |
| | 115 | 264 | 44 | 50 | 2178 | 365 |
| | 116 | 259 | 43 | 51 | 2015 | 360 |
| * | 117 | 268 | 17 | 32 | 2268 | 355 |
| | 118 | 258 | 48 | 55 | 2197 | 355 |
| | 119 | 264 | 42 | 52 | 2143 | 350 |
| | 120 | 277 | 34 | 46 | 2043 | 350 |
| * | 121 | 280 | 19 | 34 | 2036 | 350 |
| * | 122 | 256 | 32 | 43 | 1986 | 315 |
| * | 123 | 263 | 29 | 37 | 1975 | 315 |

According to the results shown in Table 11, when the compositions of the piezoelectric ceramics were in the range of the present invention (sample Nos. 103 to 105, 107 to 109, 112 to 116, and 118 to 120) and CoCO₃ was added as the first accessory component, the piezoelectric properties were maintained so as not to cause any practical problems, and furthermore, firing could be performed at a low temperature, such as 1,000° C. or less, as was the case in which Bi₂O₃ was added.

On the other hand, in the cases of sample Nos. 101, 102, 111, 122 and 123 in which the primary component having the composition represented by (Ag_{1-x-y}LiₓK_{y})NbO₃ was outside the ranges (0.075≦x<0.4, 0.03≦y<0.3) of the present invention, as was the case in which Bi₂O₃ was added, the Curie point was less than 350° C.

In the cases of sample Nos. 106, 110, 117 and 121 in which the addition amount of CoCO₃ (in the form of CoO₂) was more than 10 parts by weight, the electromechanical coupling factor κ₃₃ was small, such as less than 20%, as was the case in which Bi₂O₃ was added.

TABLE 12

| | | | (%) | (pC/N) | (Hz · m) | (° C.) |
|---|---|---|---|---|---|---|
| * | 124 | 376 | 33 | 42 | 2105 | 155 |
| * | 125 | 191 | 37 | 39 | 2166 | 280 |
| | 126 | 249 | 49 | 56 | 2237 | 350 |
| | 127 | 253 | 48 | 52 | 2201 | 350 |
| | 128 | 257 | 46 | 48 | 2214 | 355 |
| * | 129 | 260 | 18 | 37 | 2076 | 355 |
| | 130 | 298 | 44 | 36 | 2153 | 360 |
| | 131 | 303 | 45 | 37 | 2098 | 350 |
| | 132 | 314 | 43 | 36 | 2179 | 350 |
| * | 133 | 297 | 17 | 35 | 2049 | 355 |
| * | 134 | 341 | 39 | 31 | 2257 | 320 |
| | 135 | 257 | 44 | 47 | 2134 | 360 |
| | 136 | 268 | 40 | 29 | 2015 | 370 |
| | 137 | 250 | 43 | 33 | 2315 | 360 |
| | 138 | 246 | 45 | 36 | 2210 | 355 |
| | 139 | 258 | 47 | 40 | 2046 | 350 |
| * | 140 | 267 | 19 | 27 | 2218 | 350 |
| | 141 | 255 | 47 | 52 | 2176 | 350 |
| | 142 | 263 | 41 | 48 | 2199 | 350 |
| | 143 | 271 | 34 | 41 | 2065 | 350 |
| * | 144 | 284 | 19 | 25 | 2043 | 350 |
| * | 145 | 258 | 32 | 29 | 1978 | 315 |
| * | 146 | 271 | 29 | 26 | 1976 | 320 |

According to the results shown in Table 12, when the compositions of the piezoelectric ceramics were in the range of the present invention (sample Nos. 126 to 128, 130 to 132, 135 to 139, and 141 to 143), and Fe₂O₃ was added as the first accessory component, the piezoelectric properties were maintained so as not to cause any practical problems, and furthermore, firing could be performed at a low temperature, such as 1,000° C. or less, as was the case in which Bi₂O₃ was added.

On the other hand, in the cases of sample Nos. 124, 125, 134, 145, and 146 in which the primary component having the composition represented by (Ag_{1-x-y}LiₓK_{y})NbO₃ was outside the ranges (0.075≦x<0.4, 0.03≦y<0.3) of the present invention, as was the case in which Bi₂O₃ was added, the Curie point was less than 350° C.

In the cases of sample Nos. 129, 133, 140 and 144 in which the addition amount of Fe₂O₃ (in the form of FeO₂) was more than 10 parts by weight, as was the case in which Bi₂O₃ was added, the electromechanical coupling factor κ₃₃ was small, such as less than 20%.

### EXAMPLE 2

In this example, sample Nos. 201 to 220 were formed in a manner similar to that in Example 1, except that two of Fe₂O₃, CoCO₃, NiO, CuO, ZnO and Bi₂O₃ in the form of powder were selected and were then weighed so as to obtain the composition ratios shown in Table 13 to the primary component represented by (Ag_{1-x-y}LiₓK_{y})NbO₃, which was prepared to have x and y in the ranges of the present invention. Subsequently, in a manner similar to that in Example 1, the relative dielectric constant εᵣ, electromechanical coupling factor κ₃₃ in a thickness vibration mode, piezoelectric constant d₃₃ in a thickness vibration mode, resonant frequency constant N in a thickness vibration mode, and the Curie point of each of the individual samples were measured, and the results thereof are shown in Table 14. Samples provided with * in the table have compositions which are out of the range of the present invention.

TABLE 13

| | | x | y | | | | | | | (° C.) |
|---|---|---|---|---|---|---|---|---|---|---|
| | 201 | 0.075 | 0.03 | 0.005 | | 0.005 | | | | 960 |
| | 202 | 0.075 | 0.03 | | 2 | | 2 | | | 960 |
| | 203 | 0.075 | 0.03 | | | | | 5 | 5 | 940 |
| * | 204 | 0.075 | 0.03 | | | | | 5 | 6 | 940 |
| | 205 | 0.075 | 0.20 | | | | 0.005 | | 0.005 | 980 |
| | 206 | 0.075 | 0.20 | | | 2 | | 2 | | 980 |
| | 207 | 0.075 | 0.20 | 5 | 5 | | | | | 960 |
| * | 208 | 0.075 | 0.20 | 6 | 5 | | | | | 960 |
| * | 209 | 0.200 | 0.10 | | | | | | | 1020 |
| | 210 | 0.200 | 0.10 | 2 | | | | | 2 | 940 |
| | 211 | 0.200 | 0.10 | | | | 5 | 5 | | 940 |
| * | 212 | 0.200 | 0.10 | | | | 6 | 5 | | 940 |
| | 213 | 0.300 | 0.03 | 0.005 | 0.005 | | | | | 960 |
| | 214 | 0.300 | 0.03 | | | 2 | 2 | | | 960 |
| | 215 | 0.300 | 0.03 | | 5 | 5 | | | | 940 |
| * | 216 | 0.300 | 0.03 | | 5 | 6 | | | | 940 |
| | 217 | 0.300 | 0.20 | | | 0.005 | | 0.005 | | 960 |
| | 218 | 0.300 | 0.20 | | 2 | | | 2 | | 940 |
| | 219 | 0.300 | 0.20 | | | 5 | 5 | | | 940 |
| * | 220 | 0.300 | 0.20 | | | 5 | 6 | | | 940 |

TABLE 14

| | | | (%) | (pC/N) | (Hz · m) | (° C.) |
|---|---|---|---|---|---|---|
| | 201 | 273 | 43 | 51 | 2234 | 350 |
| | 202 | 269 | 35 | 47 | 2056 | 350 |
| | 203 | 275 | 36 | 40 | 2153 | 355 |
| * | 204 | 249 | 17 | 32 | 2314 | 355 |
| | 205 | 326 | 44 | 48 | 2295 | 360 |
| | 206 | 330 | 37 | 46 | 2168 | 360 |
| | 207 | 332 | 34 | 42 | 2495 | 355 |
| * | 208 | 351 | 18 | 34 | 2096 | 365 |
| * | 209 | 249 | 38 | 50 | 2218 | 380 |
| | 210 | 258 | 34 | 47 | 2169 | 375 |
| | 211 | 264 | 31 | 45 | 2205 | 375 |
| * | 212 | 259 | 18 | 35 | 2167 | 380 |
| | 213 | 244 | 41 | 48 | 2098 | 365 |
| | 214 | 257 | 37 | 44 | 2213 | 360 |
| | 215 | 263 | 32 | 41 | 2271 | 360 |
| * | 216 | 267 | 17 | 30 | 2143 | 365 |
| | 217 | 246 | 52 | 63 | 2184 | 360 |
| | 218 | 273 | 48 | 57 | 2096 | 355 |
| | 219 | 264 | 39 | 51 | 2103 | 360 |
| * | 220 | 257 | 19 | 31 | 2214 | 365 |

According to the results shown in Table 14, when two types of metal oxides were selected as the first accessory component and the total addition amount of the metal oxides was in the range of the present invention (sample Nos. 201 to 203, 205 to 207, 210, 211, 213 to 215, and 217 to 219), as was the case in which only one oxide was added, the piezoelectric properties were maintained so as not to cause any practical problems, and furthermore, firing could be performed at a low temperature, such as 1,000° C. or less.

On the other hand, in the cases of sample Nos. 204, 208, 212, 216 and 220 in which the total addition amount of the two types of metal oxides (in the form of MO₂) was more than 10 parts by weight, the electromechanical coupling factor κ₃₃ was small, such as less than 20%. In addition, in sample 209 in which no metal oxide was added, the firing temperature was higher than 1,000° C., such as 1,020° C.

That is, it was found that even in the case in which at least two types of oxides of Fe, Co, Ni, Cu, Zn and Bi were selected as the first accessory component, when the total addition amount was in the range of the present invention, as was the case in which only one type of metal oxide among those mentioned above was added, firing could be performed at a low temperature, such as 1,000° C. or less.

When a plurality of compounds was selected as the first accessory component, and the total addition amount was in the range of the present invention (in the range of 0.01 to 10 parts by weight to the primary component), oxides of Fe, Co, Ni, Cu, Zn and Bi may be freely used in combination, and in addition, at least three types may be selected and added.

### EXAMPLE 3

In this example, oxides of Mn and Si were each added as a second accessory component, and the influence thereof was investigated.

(1) Preparation of Primary Component and Addition of First and Second Components

In a manner similar to that in Example 1, the primary component was prepared. Next, 6 types of powders, Fe₂O₃, CoCO₃, NiO, CuO, ZnO Bi₂O₃ were each weighed as the first accessory component, and MnCO₃ and SiO₂ in powder form were each weighted as the second accessory component so as to obtain the composition ratios shown in Table 15, followed by the process performed in a manner similar to that in Example 1, thereby forming dried powder used as a raw material for piezoelectric ceramic. In this case, x and y of the primary component having a composition represented by (Ag_{1-x-y}LiₓK_{y})NbO₃ and the addition amount of the first accessory component were set in the range of the present invention, and the addition amount of the second accessory component was changed in and out of the range of the present invention. Samples provided with * in the table have compositions which are out of the range of the present invention.

(2) Preparation and Evaluation of Samples

Subsequently, after firing was performed at a temperature shown in Table 15 in a manner similar to that in Example 1, sample Nos. 301 to 315 were obtained, and the piezoelectric properties thereof were measured as was the case of Example 1. The results are shown in Table 16.

TABLE 15

| | | x | y | | | | | | | | | (° C.) |
|---|---|---|---|---|---|---|---|---|---|---|---|---|
| | 301 | 0.075 | 0.20 | | | | | | 0.5 | 3.0 | 0.0 | 960 |
| | 302 | 0.075 | 0.20 | | | | | 0.5 | | 5.0 | 0.0 | 940 |
| * | 303 | 0.075 | 0.20 | | | | 0.05 | | | 6.0 | 0.0 | 940 |
| | 304 | 0.075 | 0.20 | | | | 0.05 | | | 0.0 | 0.2 | 960 |
| | 305 | 0.200 | 0.10 | | 0.01 | | | | | 0.0 | 2.0 | 940 |
| | 306 | 0.200 | 0.10 | | 0.01 | | | | | 0.0 | 3.0 | 920 |
| | 307 | 0.200 | 0.10 | 0.02 | | 0.03 | | | | 0.0 | 5.0 | 920 |
| * | 308 | 0.200 | 0.10 | 2 | | | 3 | | | 0.0 | 6.0 | 940 |
| | 309 | 0.300 | 0.03 | | | | | 4 | 5 | 0.2 | 0.2 | 960 |
| | 310 | 0.300 | 0.03 | 0.02 | | 0.03 | | | | 3.0 | 2.0 | 920 |
| | 311 | 0.300 | 0.03 | | 2 | | 3 | | | 3.0 | 0.0 | 960 |
| | 312 | 0.300 | 0.03 | | | | | 4 | 5 | 0.0 | 2.0 | 940 |
| * | 313 | 0.300 | 0.20 | 0.02 | | 0.03 | | | | 6.0 | 0.0 | 940 |
| * | 314 | 0.300 | 0.20 | | 2 | | 3 | | | 0.0 | 6.0 | 940 |
| * | 315 | 0.300 | 0.20 | | | | | 4 | 5 | 3.0 | 3.0 | 940 |

TABLE 16

| | | | (%) | (pC/N) | (Hz · m) | (° C.) |
|---|---|---|---|---|---|---|
| | 301 | 320 | 35 | 47 | 2219 | 345 |
| | 302 | 298 | 40 | 56 | 2713 | 340 |
| * | 303 | 267 | 19 | 37 | 2689 | 335 |
| | 304 | 295 | 31 | 49 | 2816 | 350 |
| | 305 | 246 | 41 | 49 | 2763 | 365 |
| | 306 | 230 | 37 | 45 | 2766 | 365 |
| | 307 | 246 | 42 | 47 | 2732 | 360 |
| * | 308 | 290 | 17 | 36 | 2873 | 365 |
| | 309 | 271 | 34 | 43 | 2773 | 370 |
| | 310 | 246 | 38 | 48 | 2772 | 360 |
| | 311 | 276 | 38 | 47 | 2543 | 360 |
| | 312 | 295 | 43 | 46 | 2329 | 365 |
| * | 313 | 245 | 17 | 38 | 2898 | 355 |
| * | 314 | 235 | 18 | 34 | 2846 | 360 |
| * | 315 | 235 | 18 | 34 | 2846 | 355 |

According to the results shown in Table 16, when MnCO₃ and/or SiO₂ in the form of MnO₂ and/or SiO₂, respectively, was added as the second accessory component in an amount within the range of the present invention (5 parts by weight or less) to 100 parts by weight of the primary component represented by (Ag_{1-x-y}LiₓK_{y})NbO₃, as in the cases of sample Nos. 301, 302, 304 to 307, and 309 to 312, a electromechanical coupling factor κ₃₃ (20% or more) which was equivalent to that obtained when the above components were not added, could be obtained, the Curie point was also substantially equivalent to that obtained in Example 1, and furthermore, firing could be performed at a lower temperature (920 to 960° C.) than the temperature (940 to 1,000° C.) in Example 1.

The total amount of MnCO₃ and/or SiO₂ in the form of MnO₂ and SiO₂, respectively, as the second accessory component may be controlled to be 5 parts by weight or less, and it was found in samples 301, 302, 304 to 307, 311, and 312 that one may be added, or that as the cases of samples 309 and 310, two components may be added.

On the other hand, when the addition amount of the second accessory component was more than the upper limit (5 parts by weight) of the range of the present invention, as in the cases of sample Nos. 303, 308, and 313 to 315, all electromechanical coupling factors κ₃₃ were small, such as less than 20%. That is, it was found that by adding 5 parts by weight or less of the second accessory component to 100 parts by weight of the primary component, the sintering temperature can be further decreased without degrading the piezoelectric properties.

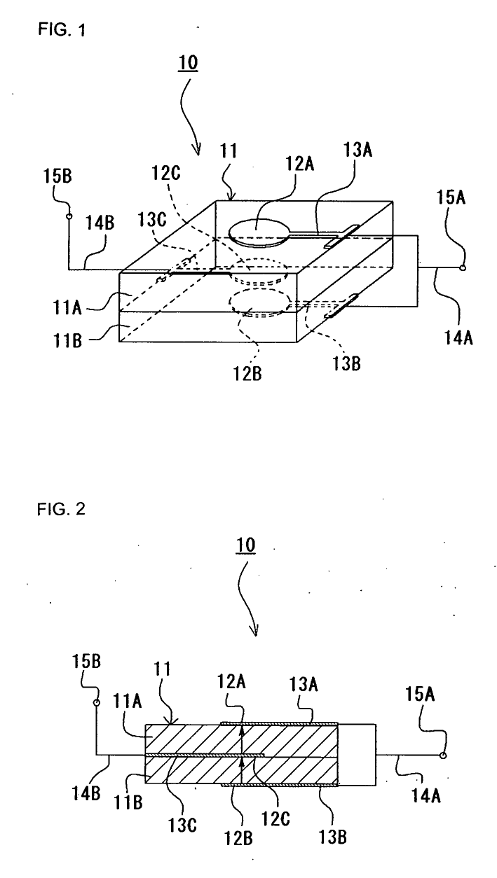

Next, one embodiment of a piezoelectric ceramic element formed by using the piezoelectric ceramic of the present invention will be described with reference to FIGS. 1 and 2. In the figures, FIG. 1 is a perspective view showing a piezoelectric ceramic vibrator which is one embodiment of the piezoelectric ceramic element of the present invention, and FIG. 2 is a cross-sectional view of the piezoelectric ceramic vibrator shown in FIG. 1.

As shown in FIGS. 1 and 2, for example, a piezoelectric ceramic vibrator 10 of this embodiment includes a piezoelectric ceramic 11 having a rectangular parallelepiped shape, which is formed from the piezoelectric ceramic according to the present invention, circular vibration electrodes 12A, 12B, and 12C which are provided, respectively, on the top surface and on the bottom surface of the piezoelectric ceramic 11, and at a place approximately at the center therebetween in the thickness direction, and lead electrodes 13A, 13B and 13C each having a T shape, one-end thereof connected to one-end of the respective vibration electrodes 12A, 12B and 12C, with the other ends extending to the sides of the piezoelectric ceramic 11.

The piezoelectric ceramic 11 is formed, for example, of piezoelectric ceramic layers 11A and 11B laminated to each other, and the vibration electrode 12C is formed at the interface between the piezoelectric ceramic layers 11A and 11B, which is approximately at the center in the thickness direction. As shown by arrows in FIG. 2, the top and the bottom vibration electrodes 12A and 12B are processed by a polarization treatment in the same direction. The top and the bottom vibration electrodes 12A and 12B and the respective lead electrodes 13A and 13B are formed so as to overlap each other, and the lead electrode 13C connected to the middle vibration electrode 12C is formed in a direction opposite to that of the lead electrodes 13A and 13B. In addition, the lead electrodes 13A, 13B and 13C are each formed to have a T shape so that the other ends are along one-side of the piezoelectric ceramic 11.

The top and the bottom vibration electrodes 12A and 12B are connected to an exterior electrode 15A via the lead electrodes 13A and 13B and a lead wire 14A, and the middle vibration electrode 12C is connected to another exterior electrode 15B via the lead electrode 13C and another lead wire 14B.

The piezoelectric ceramic vibrator 10 of this embodiment contains no Pb and can be manufactured by low-temperature firing at 1,000° C. or less, and hence a piezoelectric ceramic vibrator with a small environmental burden can be provided. In addition, since low-temperature firing can be performed, an internal electrode containing a small amount of Pd can be used, and as a result, the manufacturing cost can be reduced.

The present invention is not limited at all to the above examples, and without departing from the spirit and the scope of the present invention, modifications may be included in the present invention. For example, as the piezoelectric ceramic element, besides the piezoelectric ceramic vibrator described above, for example, the present invention may be widely applied to known piezoelectric ceramic elements, such as a piezoelectric ceramic filter and a piezoelectric ceramic oscillator.

### INDUSTRIAL APPLICABILITY

Accordingly, the present invention can be preferably applied to piezoelectric ceramic elements used, for example, for electronic devices and home appliances.

1. A piezoelectric ceramic comprising: a primary component having a composition represented by (Ag_{1-x-y}LiₓK_{y})NbO₃ in which 0.075≦x<0.4 and 0.03≦y<0.3 and 0.01 to 10 parts by weight calculated as MO₂ with respect to 100 parts by weight of the primary component of at least one oxide of M, wherein M is selected from the group consisting of Fe, Co, Ni, Cu, Zn and Bi.

2. The piezoelectric ceramic according to claim 1, wherein an oxide of Mn or Si, or both, is present in an amount of 5 parts by weight or less calculated as MnO₂ and SiO₂, respectively, to 100 parts by weight of the primary component.

3. The piezoelectric ceramic according to claim 2, wherein 0.075≦x<0.3

4. The piezoelectric ceramic according to claim 3, wherein 0.1≦y<0.2.

5. The piezoelectric ceramic according to claim 4, wherein the amount of said an oxide of Mn or Si, or both, is at least 0.2 part by weight per 100 parts by weight of the primary component.

6. The piezoelectric ceramic according to claim 5, wherein M is only one member of said group.

7. The piezoelectric ceramic according to claim 5, wherein M is more than one member of said group.

8. The piezoelectric ceramic according to claim 1, wherein 0.075≦x<0.3

9. The piezoelectric ceramic according to claim 8, wherein 0.1≦y<0.2.

10. The piezoelectric ceramic according to claim 9 wherein the amount of said an oxide of Mn or Si, or both, is at least 0.2 part by weight per 100 parts by weight of the primary component.

11. The piezoelectric ceramic according to claim 1, wherein M is only one member of said group.

12. The piezoelectric ceramic according to claim 1, wherein M is more than one member of said group.

13. A piezoelectric ceramic element comprising the combination of a piezoelectric ceramic according to claim 12 and electrodes.

14. A piezoelectric ceramic element comprising the combination of a piezoelectric ceramic according to claim 11 and electrodes.

15. A piezoelectric ceramic element comprising the combination of a piezoelectric ceramic according to claim 10 and electrodes.

16. A piezoelectric ceramic element comprising the combination of a piezoelectric ceramic according to claim 9 and electrodes.

17. A piezoelectric ceramic element comprising the combination of a piezoelectric ceramic according to claim 8 and electrodes.

18. A piezoelectric ceramic element comprising the combination of a piezoelectric ceramic according to claim 4 and electrodes.

19. A piezoelectric ceramic element comprising the combination of a piezoelectric ceramic according to claim 2 and electrodes.

20. A piezoelectric ceramic element comprising the combination of a piezoelectric ceramic according to claim 1 and electrodes.
